(19) United States
(12) Patent Application Publication
(10) Pub. No.: US 2014/0196765 A1
(43) Pub. Date: Jul. 17, 2014

(54) SYSTEM OF VERTICALLY MOUNTING AN ARRAY OF CYLINDRICAL TUBULAR SOLAR PHOTOVOLTAIC CELLS

(71) Applicants: Vinh Minh Glisttenmeer Lam, Hayword, CA (US); Ethan Lam, Fremont, CA (US); Megan Lam, Fremont, CA (US); Victor Lam, Fremont, CA (US)

(72) Inventors: Vinh Minh Glisttenmeer Lam, Hayword, CA (US); Ethan Lam, Fremont, CA (US); Megan Lam, Fremont, CA (US); Victor Lam, Fremont, CA (US)

(21) Appl. No.: 13/740,979

(22) Filed: Jan. 14, 2013

(51) Int. Cl. H01L 31/042; H01L 31/18

(52) U.S. Cl. CPC H01L 31/0422; H01L 31/18
USPC 136/251; 29/890.033

(57) ABSTRACT

A system of harvesting solar energy is described whereby cylindrical tubular solar photovoltaic cells are vertically mounted into a high density array with their longitudinal axis in the vertical direction.

### FIELD OF THE INVENTION

This invention relates to the field of harvesting solar energy using a system of vertically mounting a high density array of cylindrical tubular solar photovoltaic cells.

### BACKGROUND OF THE INVENTION

### Description of the Prior Art

### References Cited

| Patent Number or | | | |
|---|---|---|---|
| Patent Application | | | |
| Number | Date | Inventor | Field |
| 4,119,863 | Oct. 10, 1978 | Kelly | 136/248 |
| US 2008/0251115 A1 | Sep. 28, 2006 | Thompson et al | 136/251 |
| 7,235,736 | Jun. 26, 2007 | Buller et al | 136/251 |
| US 2010/0236604 A1 | Feb. 26, 2010 | Depaoli | 136/246 |
| US 2011/0041834 A1 | Aug. 7, 2010 | Liao | 126/605 |
| 8,196,572 | Jun. 12, 2012 | Edmunds | 126/600 |

There is a need in our world for a more effective method of harvesting solar energy. Developing more efficient solar photovoltaic cell is one way to increase the amount of solar energy collected. Another way to increase the harvesting of solar energy is by packing or mounting the photovoltaic cells in such a way as to increase the amount of solar energy collected without necessarily increasing the efficiency of the solar cell.

The prior arts have continuously strived for greater and greater efficiency in the design of the photovoltaic cell. However, there is a limit to the efficiency attainable because of the limitation of materials used in photovoltaic cell. For this reason, progress in increasing the efficiency of the individual solar cell must necessarily slow down. A better system to increase the amount of energy collected may be simply to change the configuration of the photovoltaic array or by automatically tracking the sun so that the solar panel may capture the maximum amount of sunlight. For example, Edmunds, in his patent U.S. Pat. No. 8,196,572, describes a new configuration for the solar panel in the shape of a cone. Buller et al, in their patent U.S. Pat. No. 7,235,736, describes a cylindrical tubular solar cell that can absorb sunlight in any direction from reflection, refraction, diffuse sunlight, as well as direct sunlight. Other prior arts have used an automatic tracking system which rotates the flat solar panels to face the sun as the position of the sun changes. Tracking the sun provides the best solution to harvest the greatest amount of energy. However, the control system required to track the sun makes such a solar panel system too expensive to be affordable. Cylindrical solar cells promise to be the best configuration for harvesting sunlight in any direction. However, the prior arts stack the cylindrical solar cells in a horizontal array, which collect the same amount of solar energy as conventional flat solar panel. The prior arts have many varieties of solar cells in different configurations and shapes. However, all these configurations in arraying the solar cells prove to be less than efficient in harvesting the maximum amount of solar energy. Our invention is a system of mounting the solar cells in such as way as to maximize the collection of solar energy.

### SUMMARY OF THE INVENTION

The objective of this invention is to configure the solar cell array in a way that maximizes the amount of solar energy collected. Our system comprises a frame which supports the solar cells. The frame comprises of an array of vertical supporting rods, evenly spaced and perpendicular to the ground. Cylindrical tubular solar photovoltaic cells with a hollow inner core will be inserted over the supporting rods on the frame. Every supporting rod will support a cylindrical tubular solar cell. The supporting rods are inserted into the inner hollow core of the cylindrical tubular solar cells, providing structural support to the vertically aligned cylindrical tubular solar cell.

Our system utilizes an existing solar cell as described in Patent U.S. Pat. No. 7,235,736 which describes a cylindrical tubular solar cell. This type of tubular solar cells was mass produced by the former Solyndra company. This type of solar cell is tubular in shape, resulting in an empty core in the center, which is filled by a volume compensator material. Our system proposes to use this type of tubular solar cell, but with the volume compensator material removed from the inner core, resulting in an empty core. Other solar cell manufacturers in the future may produce tubular solar cells that have an empty inner core through the entire tubular solar cell including openings through the caps at both ends of the tube. Our system will use this particular type of cylindrical tubular solar cell with an inner hollow empty core through the entire tube including openings at both end-caps.

Our invention is a system of mounting and configuring a specific and particular type of solar cells into an array in such a way that is novel, non-obvious and offer an improvement over the prior arts. The array configuration of vertically mounting cylindrical tubular solar photovoltaic cells is novel because it has not been tried in the prior arts before. The production of tubular solar cells has only occurred in the past decade, which makes such tubular solar cell technology a very new technology. Since the bankruptcy of Solyndra, this type of cylindrical solar tubular cells has been discontinued in production. Those skilled in the art of solar cells now find little opportunity to experiment with using cylindrical solar cells. Hence, very little progress has been made to improve the utilization of cylindrical tubular solar cells. For this reason, our system of vertically mounting and arraying cylindrical solar tubular cells is novel and will remain unique for the foreseeable future.

Our system of vertically mounting and configuring the array of cylindrical solar tubular cells is non-obvious because the prior arts have for many years utilized flat planar solar panels. Flat planar solar panels in the prior arts require mounting the planar solar panel perpendicular to the rays of the sun. Those skilled in the arts of mounting solar panels are accustomed to mounting planar solar panels in such a way as to face and track the sun. The idea of mounting cylindrical tubular solar cells into a vertical array could not have occurred to those skilled in the prior arts because cylindrical tubular solar cells are new technologies that have not been widely used in the prior arts. Furthermore, the very recent adoption of cylindrical tubular solar cells has been interrupted by the cessation of their production due to the bankruptcy of the solar cell manufacturer Solyndra, which dampens any further progress in experimenting with using cylindrical tubular solar cells. For these reasons, our invention of a system of configuring and vertically mounting cylindrical tubular solar cells into an array is non-obvious.

Our system of mounting an array of vertical cylindrical tubular solar cells offer significant improvements over the prior arts. The prior arts describe many examples of mounting a planar solar panel including incorporating motor and control system to rotate the solar panels to track the sun. However, these examples from the prior arts suffered from two major advantages. First, the cost of incorporating a motor and a control system to rotate the solar panel to track the sun make such systems too expensive to be widely used. Second, the planar solar panel from the prior arts provides only one layer of solar cells to absorb sunlight. These single layer solar panels cannot be stacked with two or more layers because the sunlight cannot pass through the first layer. Our system of mounting a vertical array of cylindrical tubular solar cells provides improvements to the above problems. First, our system utilizes an existing solar cell technology, the cylindrical tubular solar cell, which can absorb sunlight in any direction, making a sun-tracking control system unnecessary. Second, because the cylindrical tubular solar cells are long slender vertical tubes, they can be stacked into multiple vertical layers, while allowing sunlight to pass through to the other layers because sunlight can pass through the spaces between the tubular solar cells in the front layers. Thirdly, the vertical cylindrical solar cells can be produced in any length. Longer cylindrical solar cell allows more sunlight to be absorbed. Our invention describes a system of mounting long cylindrical tubular solar cells vertically into a high density array which maximizes the amount of sunlight captured by the solar array.

### BRIEF DESCRIPTION OF FIGURES

FIG. 1A shows an isometric view of the cylindrical tubular solar photovoltaic cell already in existence in the prior arts. The solar cell is tubular with an empty hollow inner core 2.

FIG. 1B shows a front view of the cylindrical tubular solar photovoltaic cell already in existence in the prior art.

FIG. 1C shows a top view of the cylindrical tubular solar photovoltaic cell already in existence in the prior art. The solar cell is tubular with an empty hollow inner core 2.

FIG. 2A shows an isometric view of the frame with four supporting legs 4 at the corners. Threaded holes 5 are arrayed onto the top surfaces of the frame.

FIG. 2B shows a top view of the frame with an array of threaded holes 5.

FIG. 2C shows a front view of the frame with an array of threaded holes 5 and legs 4.

FIG. 3A shows an isometric view of the supporting rod with thread 7 at one end.

FIG. 3B shows a front view of the supporting rod with thread 7 at one end.

FIG. 4A shows a front view of the supporting rods 6 installed into the frame 3.

FIG. 4B shows an isometric view of the supporting rods 6 installed into the frame 3.

FIG. 4C shows an isometric view of the supporting rods 6 installed into the frame 3.

FIG. 5A shows an isometric view of the cylindrical tubular solar PV cell 1 inserted over the supporting rods 6 which are installed into the frame 3.

FIG. 5B shows a front view of the cylindrical tubular solar PV cell 1 inserted over the supporting rods 6 which are installed into the frame 3.

FIG. 5C shows a top view of the cylindrical tubular solar PV cell 1 inserted over the supporting rods 6 which are installed into the frame 3.

FIG. 5D shows another isometric view of the completed solar mounting system.

### DETAILED DESCRIPTION OF SYSTEM

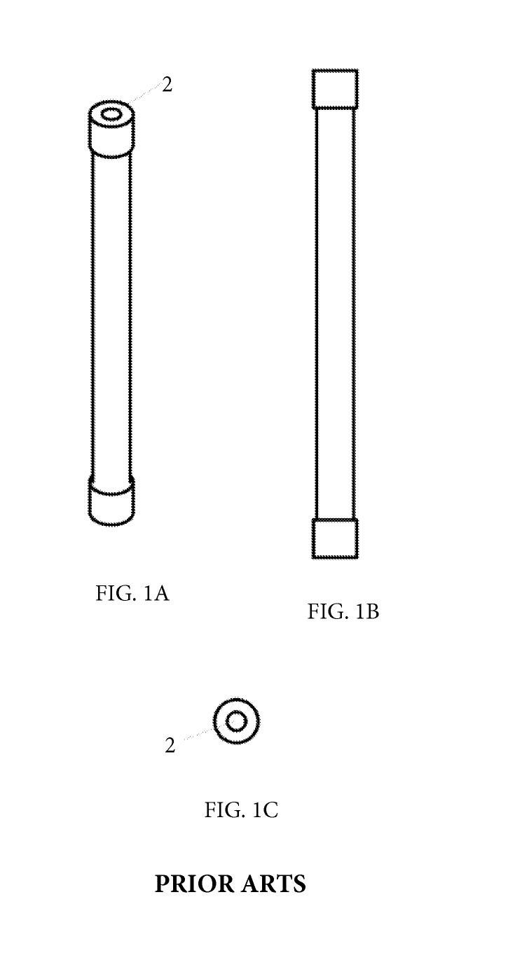

We will describe in detail our solar mounting system. Our mounting system is specifically designed to mount a particular type of solar cell. This type of solar cells is cylindrical and tubular in shape, with an inner hollow empty core. This type of cylindrical tubular solar cells has been mass produced in the prior arts by the former Solyndra Company. FIG. 1A depicts the cylindrical solar cell with an inner hollow empty core 2. This inner empty hollow core extends through the entire solar cell tube including openings at both end caps of the solar cell as depicted in FIG. 1C. FIG. 1B shows a long cylindrical solar cell which can be produced in any length. Longer solar cell tube will absorb more sunlight because of its greater surface area.

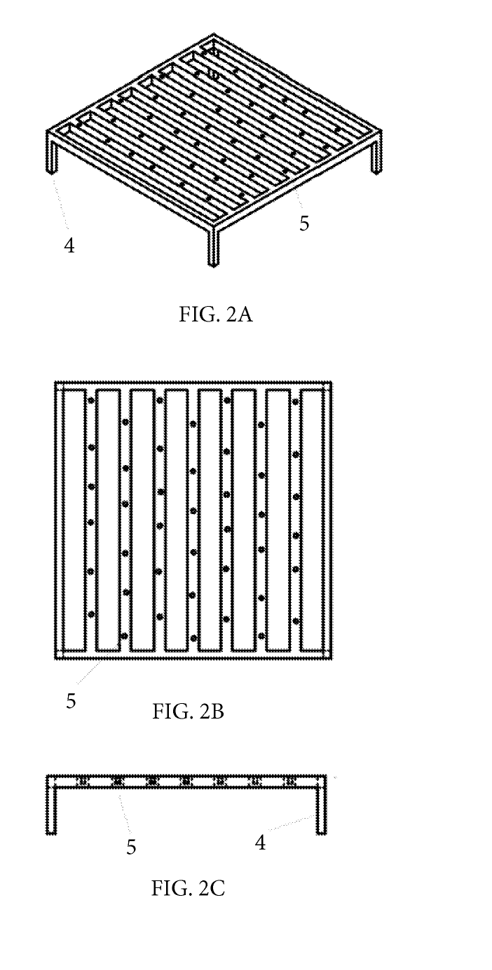

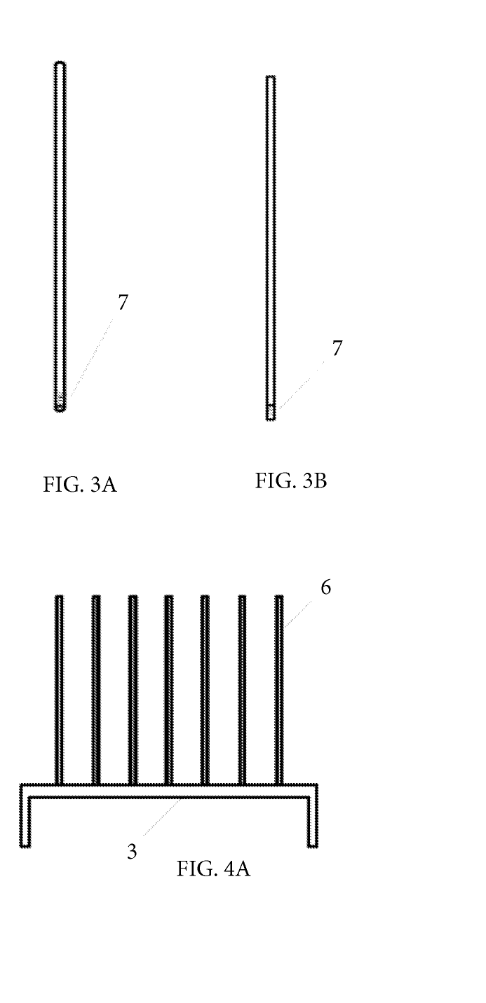

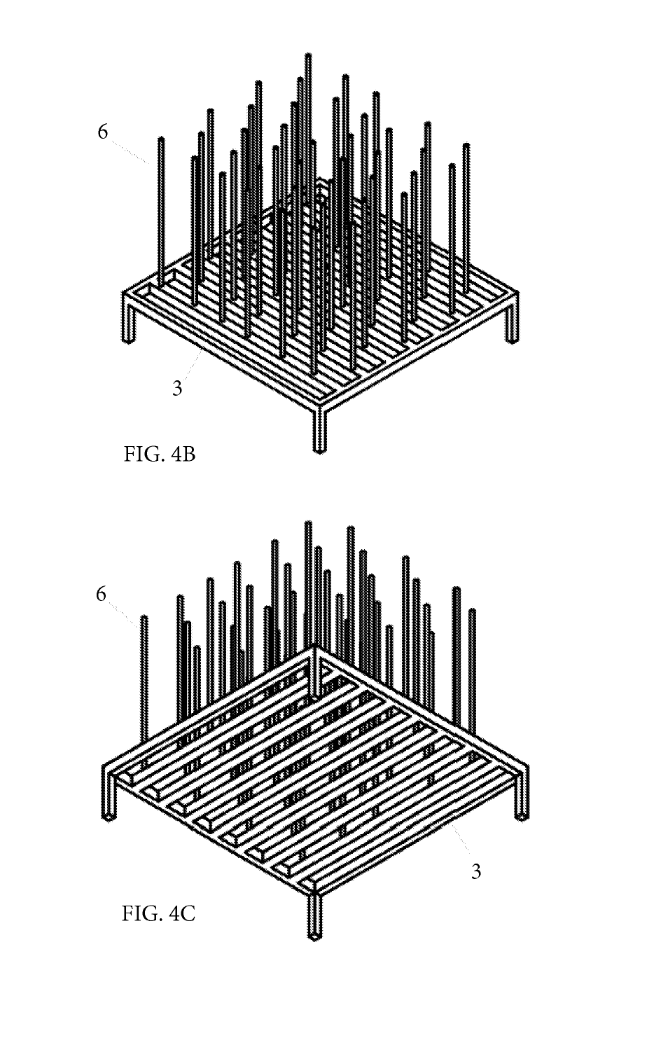

Our solar cells mounting system comprises of a frame as depicted in FIG. 2A. The frame is supported by four legs 4 at the four corners. An array of threaded holes 5 are machined into the top surface of the frame. The threaded holes can be seen in profile within the frame in FIG. 2C. The array of threaded holes 5 are evenly spaced apart and packed into a high density array. In some embodiments, the number of threaded holes 5 can be increased substantially to give a very high density array of threaded holes 5. FIG. 3A and 3B depict a supporting rod with matching thread machined into one end of the rod. The supporting rods are inserted into the frame by screwing the threaded end of the rods into the threaded hole of the frame. FIG. 4A, 4B and 4C depict the resulting solar cells mounting system when all the supporting rods 6 are inserted into the frame 3. FIG. 4A shows the front view of our solar cells mounting system. The supporting rods are vertically mounted onto the frame, with their longitudinal axis perpendicular to the surface plane of the frame. The length of the supporting rods preferably should be longer than the length of the cylindrical solar cell.

We prefer to use aluminum as the metal of choice for constructing the solar cells mounting system. Aluminum is a light weight corrosion resistant material which will facilitate installation in any environment. Furthermore, aluminum is easily molded and machined into the different components of our solar cells mounting system for ease of assembly.

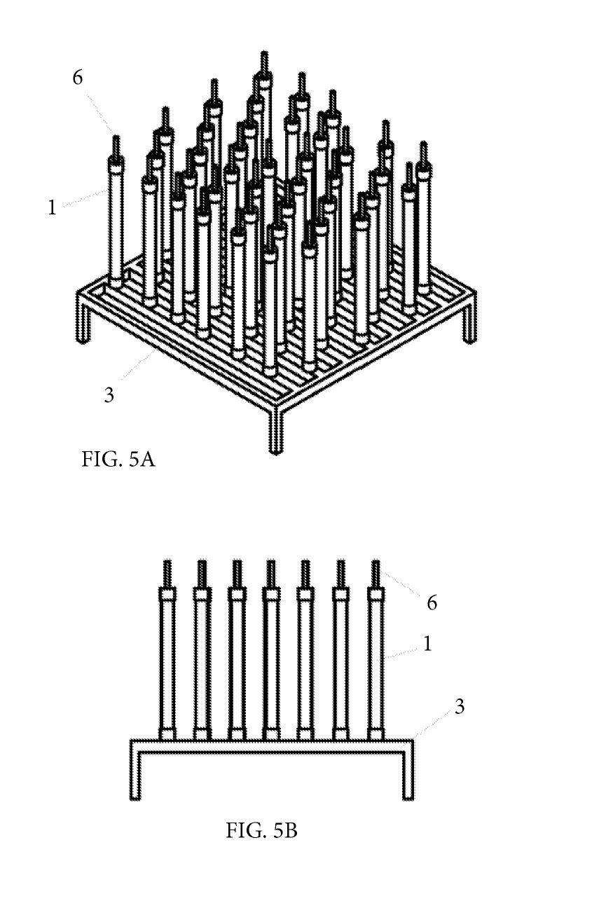

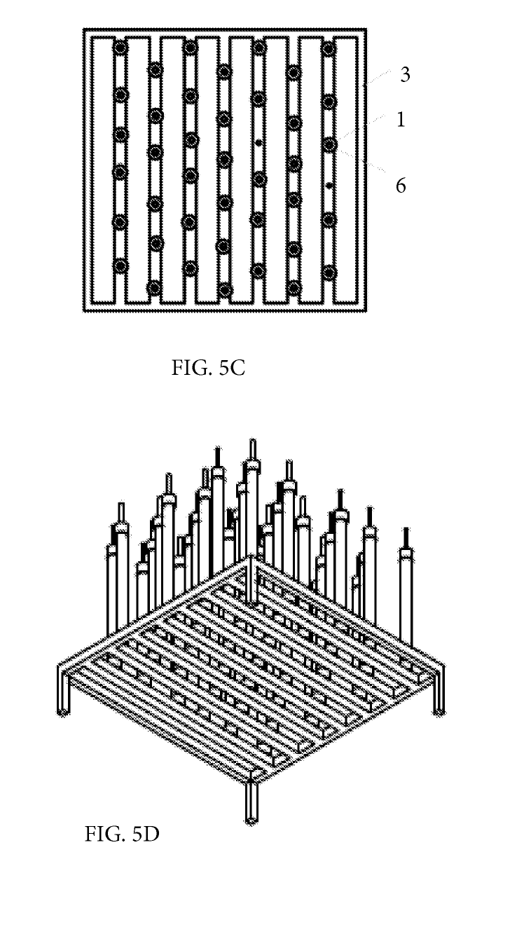

The cylindrical solar cell tubes 1 are inserted over the supporting rods 6 which have been installed onto the frame 3. The diameter of the inner hollow core 2 is slightly larger than the diameter of the supporting rods 6, which allows for ease of insertion. The length of the supporting rods 6 is preferably longer than the length of the cylindrical tubular solar cell 1, which allows for structural support of the cylindrical solar cell along its entire length. FIG. 5A, 5B, 5C and 5D depict the resulting solar cells mounting system after all the cylindrical tubular solar cells are inserted over the supporting rods. FIG. 5B clearly shows an overhang of the supporting rod 6 beyond the top of the cylindrical solar cell 1. This overhang is preferred in order to provide full structural support along the length of the cylindrical solar cell. FIG. 5C depicts the top view of the array of cylindrical solar tubular cells 1 securely mounted onto the frame 3 by supporting rods 6 inserted through the inner hollow core 2 of the tubular solar cells 1. In some embodiments, the number of cylindrical solar cells can be increased substantially to create a very high density array of cylindrical solar cells. A higher density array of cylindrical solar cells will absorb greater amount of sunlight. The preferred array density is one where the number of cylindrical solar cells is at a maximum with enough spacing between the solar cells to allow for sunlight to transmit its solar energy to every solar cell through direct, reflected, diffracted or diffuse sunlight. Furthermore, as the sun traverses through the sky, the angle of sunlight will change. Different cylindrical solar cells will thereby receive differing amount of sunlight as the sun changes its position in the sky. Regardless of the position of the sun in the sky, there will be some portions of the cylindrical solar cell array which will capture the optimum amount of sunlight. Being a passive solar cell mounting system, the array of cylindrical solar cells can capture sunlight regardless of the positions of the sun or the times of day. Even at sunset and sunrise, when the position of the sun is near the horizon, our solar cell mounting system will still capture sunlight. The ability to capture sunlight at any position of the sun or time of day is the advantage of our vertically mounted cylindrical tubular solar cell array system.

We claim:

1. A system of vertically mounting an array of cylindrical tubular solar photovoltaic cells comprising:
a frame having many supporting rods vertically attached to the top surface of said frame;
said supporting rods are perpendicular to said top surface of said frame;
an array of said supporting rods which are evenly spaced and attached to said frame;
cylindrical tubular photovoltaic solar cells, which have an inner hollow empty core with an inner core diameter slightly larger than the diameter of the supporting rods;
said cylindrical tubular photovoltaic solar cells which are inserted over the supporting rods;
multiple said cylindrical tubular photovoltaic solar cells which are arranged into an array;
said array of cylindrical tubular photovoltaic solar cells which are inserted over the array of supporting rods which are attached to the frame;
said array of cylindrical tubular photovoltaic solar cells which is vertically mounted onto said frame;
said array of cylindrical tubular photovoltaic solar cells which is perpendicular to said top surface of said frame;
said array of cylindrical tubular photovoltaic solar cells which is perpendicular to the surface of the ground;
said array of cylindrical tubular photovoltaic solar cells which can vary in number of said cylindrical solar cells;
said array of cylindrical tubular photovoltaic solar cells which can vary in length along the longitudinal axis to increase surface area for absorbing sunlight.

2. A method of mounting cylindrical solar cells comprising of:
mounting said cylindrical solar cell vertically;
mounting said cylindrical solar cell with its longitudinal axis perpendicular to the frame;
mounting said cylindrical solar cell with its longitudinal axis perpendicular to the ground;
mounting multiple said cylindrical solar cells into an array;
evenly spacing said multiple cylindrical solar cells into an array;
maximizing the number of said cylindrical solar cells in the array while retaining enough spacing between said cylindrical solar cells to allow optimum amount of sunlight to be transmitted to all solar cells.
